(19) United States
(12) Patent Application Publication
(10) Pub. No.: US 2011/0073990 A1
(43) Pub. Date: Mar. 31, 2011

(54) Capacitor and Method for Making Same

(76) Inventors: Rudolf BERGER, Regensburg (DE); Guenther RUHL, Kumhausen (DE); Kai-Olaf SUBKE, Grafing (DE)

(21) Appl. No.: 12/567,952

(22) Filed: Sep. 28, 2009

(51) Int. Cl. H01L 29/92; H01L 21/02

(52) U.S. Cl. 257/532; 438/386; 257/E21.008; 257/E29.342

(57) ABSTRACT

One or more embodiments relate to a method for making a capacitor such as a trench capacitor. The method includes: providing a substrate; forming an opening within the substrate; forming a sidewall spacer over a sidewall surface of the opening; forming a first conductive layer within the opening after forming the sidewall spacer; removing the sidewall spacer; forming a dielectric layer over the first conductive layer within the opening; and forming a second conductive layer over the dielectric layer within the opening.

### FIELD OF THE INVENTION

Generally, the present invention relates to semiconductor devices, and, in particular, to semiconductor device having capacitors.

### BACKGROUND OF THE INVENTION

Capacitors may be a part of semiconductor devices. Examples of capacitors include, but not limited to, stacked capacitors, metal-insulator-metal (MIM) capacitors, trench capacitors and vertical-parallel-plate (VPP) capacitors. For devices with high capacity per area used, surface enhancement by means of trenches may be a preferred method. There may be practical limits for the trench depth. New methods are needed for further surface gain.

### BRIEF DESCRIPTION OF THE DRAWINGS

FIGS. 1 through 10A-D (10A through 10D) show a process for making a capacitor in accordance with an embodiment of the present invention;

FIG. 11 shows a capacitor in accordance with an embodiment of the present invention;

FIGS. 12 through 21A-D show a process for making a capacitor in accordance with an embodiment of the present invention;

FIG. 22 shows a capacitor in accordance with an embodiment of the present invention; and

FIG. 23 shows a capacitor in accordance with an embodiment of the present invention.

### DETAILED DESCRIPTION OF THE INVENTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

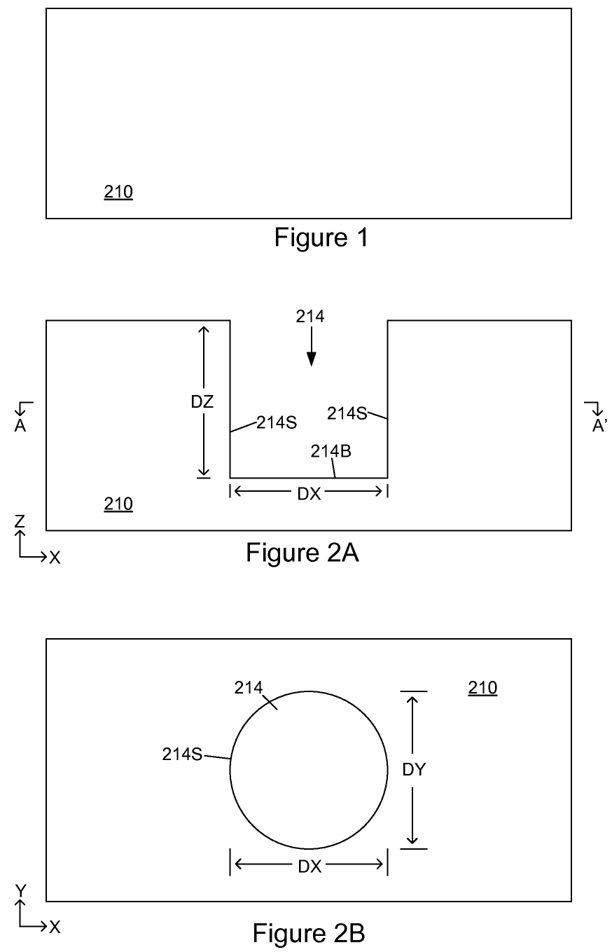

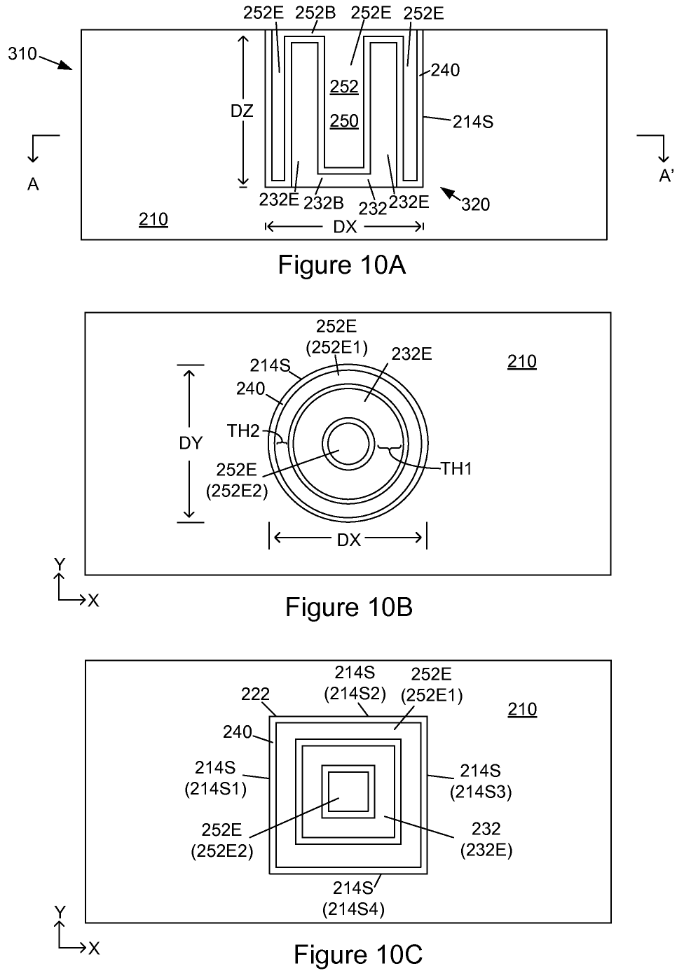

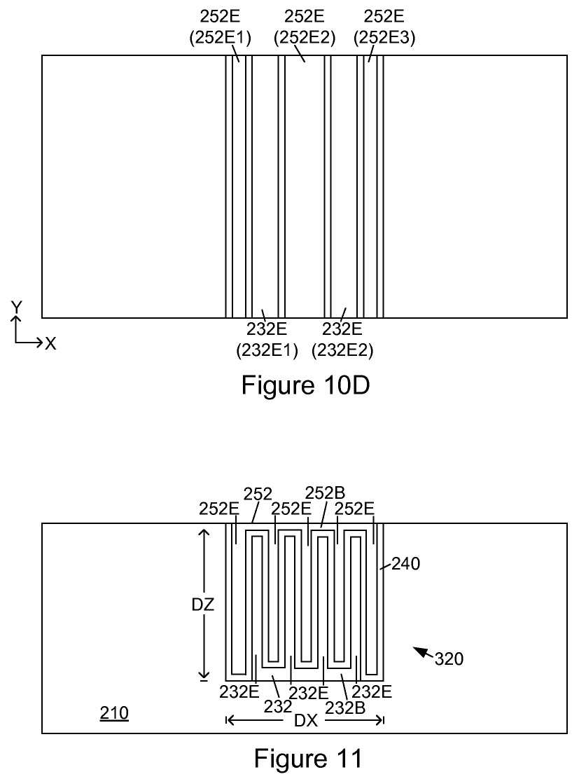

FIGS. 1 through 10A-D show a method of making a capacitor 320 shown in FIGS. 10A-D. The capacitor 320 is an embodiment of the present invention. Likewise, the method of making the capacitor 320 as depicted in FIGS. 1 through 10A-D is also an embodiment of the present invention.

FIG. 1 shows a structure which comprises a substrate 210. Generally, the substrate 210 may be any type of substrate. In one or more embodiments, the substrate 210 may be a semiconductor substrate. In one or more embodiments, the semiconductor substrate 210 may be a silicon substrate. In one or more embodiments, the semiconductor substrate may be a p-type substrate. In one or more embodiments, the semiconductor substrate may, for example, be a bulk mono-crystalline silicon substrate. In one or more embodiments, the semiconductor substrate may be a silicon-on-insulator (SOI) substrate. The SOI substrate may, for example, be formed by a SIMOX process. In one or more embodiments, the semiconductor substrate may be a silicon-on-sapphire (SOS) substrate. In one or more embodiments, the semiconductor substrate may be a germanium-on-insulator (GeOI) substrate. In one or more embodiments, the semiconductor substrate may include one or more semiconductor materials such as silicon, silicon germanium, germanium, germanium arsenide, indium arsenide, indium arsenide, indium gallium arsenide, or indium antimonide.

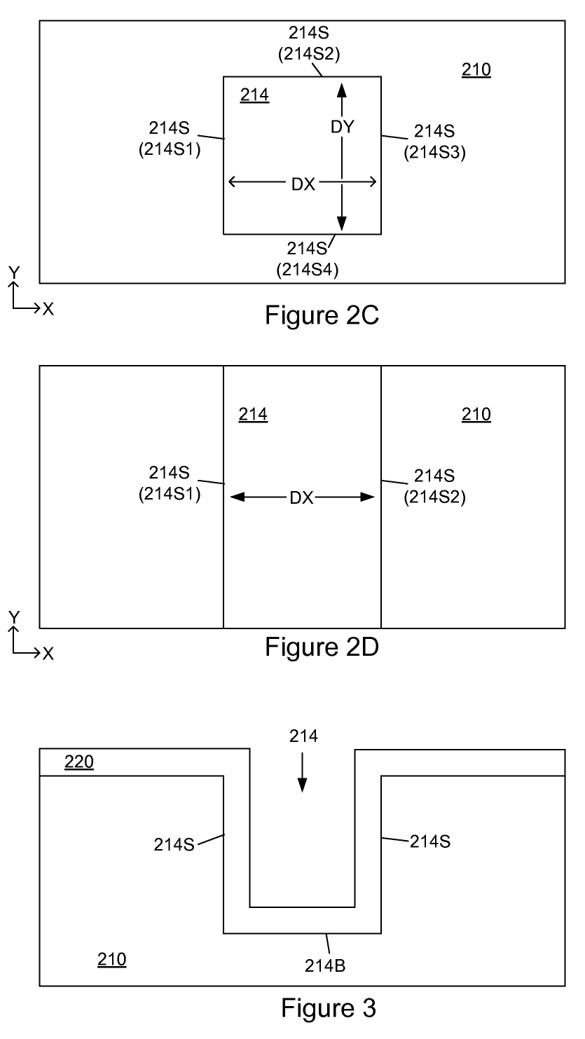

Referring to FIG. 2A, an opening 214 is formed in the substrate 210. The cross-section in FIG. 2 lies in an X-Z plane. In the embodiment shown, the opening 214 goes only partially through the substrate 210. However, in another embodiment, it is conceivable that an opening be formed that goes totally through the substrate 210.

The opening 214 may be formed as a hole or as trench. When the opening 214 is formed as a hole, the hole may have any lateral cross-sectional shape. Examples of lateral cross-sections for holes include substantially circular, substantially elliptical, substantially square and substantially rectangular. FIG. 2B shows an embodiment, where the opening 214 is a substantially cylindrical hole having a substantially circular lateral cross-section. The opening 214 shown in FIG. 2B includes a sidewall surface 214S and a bottom surface 214B. FIG. 2C shows an embodiment, wherein the opening 214 is a hole having a substantially square lateral cross section. The opening 214S includes a bottom surface 214B as well as sidewall surfaces 214S. The sidewall surfaces are depicted as sidewall surfaces 214S1, 214S2, 214S3 and 214S4. FIG. 2D shows an embodiment wherein the opening 214 is a trench. In the embodiment shown in FIG. 2D, the opening 214 includes a bottom surface 214B and sidewall surfaces 214S. The sidewall surfaces 214S are depicted as a first sidewall surface 214S1 and a second sidewall surface 214S2 spacedly disposed from the first sidewall surface 214S1. The lateral cross-sections shown in FIGS. 2B-C are through the cross-section AA′ from FIG. 2A. The cross section in FIG. 2A lies in an X-Z plane while the cross sections in FIGS. 2B-D lie in the X-Y plane.

Generally, the opening 214 may include a bottom surface and at least one sidewall surface (one or more sidewall surfaces). The bottom surface of the opening 214 may be formed over a conductive portion of the substrate 210.

The bottom surface 214B of the opening 214 has a first lateral dimension DX which may be in the X-direction and a second lateral dimension DY which may be in the Y-direction. In one or more embodiments DX may be substantially equal to DY. In one or more embodiments DX may be greater than DY. In one or more embodiments DX may be less than DY.

Examples of the lateral dimensions DX, DY are seen in FIGS. 2B-D. The opening 214 also has a depth DZ in the Z-direction which is substantially perpendicular to both the X and Y directions.

Referring to FIG. 2B, when the opening 214 has a substantially circular cross-section, the first lateral dimension DX is substantially the same as the second lateral dimension DY and may represent the diameter or width of the opening 214. Referring to FIG. 2C, when the opening 214 has a substantially square cross-section, the first lateral dimension DX is also substantially the same as the second lateral dimension DY. In the case in which the lateral cross-section of the opening 214 is substantially oval or substantially rectangular, the first lateral dimension DX may be different from the second lateral dimension DY and the first lateral dimension DX may represent a width of the opening 214. Referring to FIG. 2D, in the case in which the opening 214 is formed as a trench, the first lateral dimension DX may also represent a width of the trench.

In one or more embodiments, the lateral dimension DX of the opening 214 may be around 2 microns or less. In one or more embodiments, the depth DZ of the opening DZ may be around 30 microns or greater. In one or more embodiments, the depth DZ of the opening DZ may be around 40 microns or greater.

As an optional step in the formation of the capacitor structure, after the formation of the opening 214, a region of the substrate adjacent or proximate to the opening 214 may be n and/or p doped to form an n or p doped monocrystalline region adjacent or proximate to the opening 214. As explained below, this n or p doped monocrystalline region may be a portion of the first electrode of the capacitor structure.

Referring to FIG. 3, a layer 220 may be formed over the top surface of the substrate 210 as well as within the opening 214. In one or more embodiments, the layer 220 may be formed by a deposition process. In one or more embodiments, the layer 220 may be substantially conformally deposited over the sidewall surface(s) 214S and bottom surface 214B of the opening 214.

In one or more embodiments, the layer 220 may comprise a carbon material. In one or more embodiments, the layer 220 may consist essentially of a carbon material. The carbon material may be any material which includes carbon (C). In one or more embodiments, the carbon material may be any material that includes carbon atoms. In one or more embodiments, the carbon material may be molecular carbon. In one or more embodiments, the carbon material may be a carbon allotrope. Examples of carbon allotropes include, but are not limited to, diamond, graphite, amorphous carbon, buckministerfullerenes (such as buckyballs, carbon nanotudes and carbon nanobuds), glassy carbon, carbon nanofoam, lonsdaleite (hexagonal carbon), linear acetylenic carbon, chaoite, metallic carbon, hexagonite, and prismane C8.

In one or more embodiments, the carbon material may be a material selected from the group consisting of diamond, graphite, graphene, amorphous carbon, buckministerfullerenes, glassy carbon, carbon nanofoam, lonsdaleite (hexagonal carbon), linear acetylenic carbon, chaoite, metallic carbon, hexagonite, and prismane C8, and mixtures thereof. Other materials are also possible.

Hence, in one or more embodiments, the layer 220 may comprise or consist essentially of at least one material selected from the group consisting of diamond, graphite, graphene, amorphous carbon, buckministerfullerenes (such as buckyballs, carbon nanotudes and carbon nanobuds), glassy carbon, carbon nanofoam, lonsdaleite (hexagonal carbon), linear acetylenic carbon, chaoite, metallic carbon, hexagonite, prismane C8 and mixtures thereof. Other materials are also possible.

In one or more embodiments, the layer 220 may comprise or consist essentially of a material that is dry removable. In one or more embodiments, the layer 220 may be formed of any material that can be removable without using a liquid. In one or more embodiments, the layer 220 may comprise or consist essentially of any material that is dry etchable. In one or more embodiments, the layer 220 may comprise or consist essentially a material that is etchable without using a liquid. In one or more embodiments, the layer 220 may comprise or consist essentially a material that is removable without using a liquid.

In one or more embodiments, the layer 220 may comprise or consist essentially of a material that is stable at a temperature of about 200° C. In one or more embodiments, the layer 220 may comprise or consist essentially of a material that is stable at a temperature of about 300° C. In one or more embodiments, the layer 220 may comprise or consist essentially of a material that is stable at a temperature of about 350° C. In one or more embodiments, the layer 220 may comprise or consist essentially of a material that is stable at a temperature of about 400° C. In one or more embodiments, the layer 220 may comprise or consist essentially of a material that is stable at a temperature of about 500° C. In one or more embodiments, the layer 220 may comprise or consist essentially of a material that is stable at a temperature of about 600° C. In one or more embodiments, the layer 220 may comprise or consist essentially of a material that is stable at a temperature of about 650° C. In one or more embodiments, the layer 220 may comprise or consist essentially of a material that is stable at a temperature of about 650° C. In one or more embodiments, the layer 220 may comprise or consist essentially of a material that is stable at a temperature of about 700° C. In one or more embodiments, the layer 220 may comprise or consist essentially of a material that is stable at a temperature of about 750° C. In one or more embodiments, the layer 220 may comprise or consist essentially of a material that is stable at a temperature of about 800° C.

It is noted that, in one or more embodiments, a material which is stable at a particular temperature TEMP may also be stable at temperatures below TEMP. For example, a material which is stable at about 200° C. may also be stable at temperatures below about 200° C.

In one or more embodiments, the layer 220 may comprise or consist essentially of any material that is stable at a temperature of about 200° C. and also dry removable. In one or more embodiments, the layer 220 may comprise or consist essentially of a material that is stable at a temperature of about 300° C. and is also dry removable. In one or more embodiments, the layer 220 may comprise or consist essentially of a material that is stable at a temperature of about 400° C. and is also dry removable. In one or more embodiments, the layer 220 may comprise or consist essentially of a material that is stable at a temperature of about 500° C. and is also dry removable. In one or more embodiments, the layer 220 may comprise or consist essentially of a material that is stable at a temperature of about 600° C. and is also dry removable. In one or more embodiments, the layer 220 may comprise or consist essentially of a material that is stable at a temperature of about 650° C. and is also dry removable. In one or more embodiments, the layer 220 may comprise or consist essentially of a material that is stable at a temperature of about 700° C. and is also dry removable. In one or more embodiments, the layer 220 may comprise or consist essentially of a material that is stable at a temperature of about 750° C. and is also dry removable. In one or more embodiments, the layer 220 may comprise or consist essentially of a material that is stable at a temperature of about 800° C. and is also dry removable.

In one or more embodiments, the stability of the material used for the layer 220 may be a thermal stability. In one or more embodiments, the layer 220 may comprise or consist essentially of a thermally stable material. In one or more embodiments, the layer 220 may comprise or consist essentially of a material which is thermally stable during the deposition or growth of the first conductive layer 230 (explained below).

In one or more embodiments, the thickness of the layer 220 may be about 1000 Angstroms or less. In one or more embodiments, the thickness of the layer 220 may be about 750 Angstroms or less. In one or more embodiments, the thickness of the layer 220 may be about 500 Angstroms or less. In one or more embodiments, the thickness of the layer 220 may be about 300 Angstroms or less.

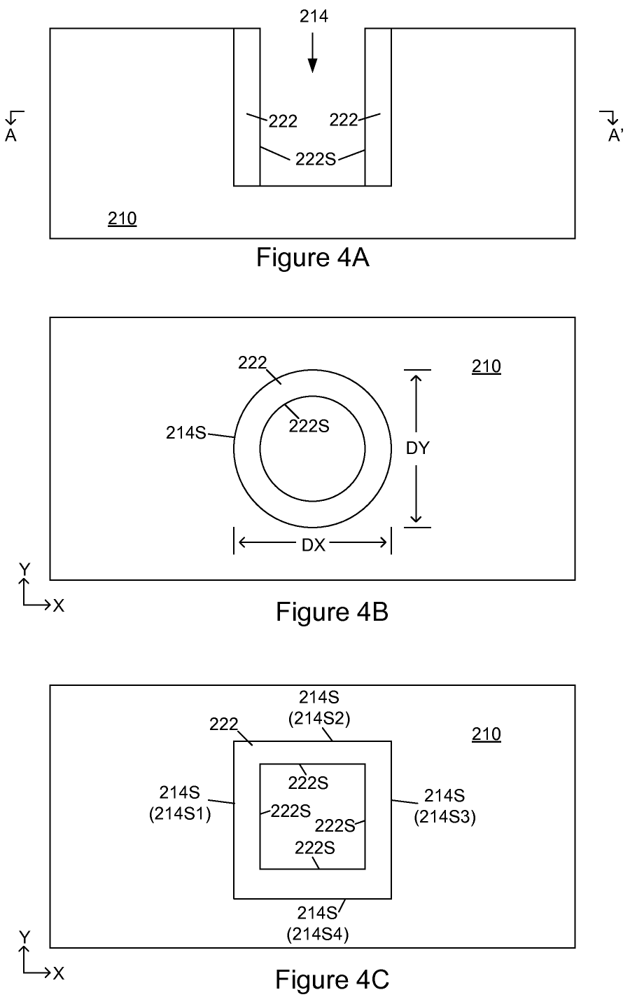

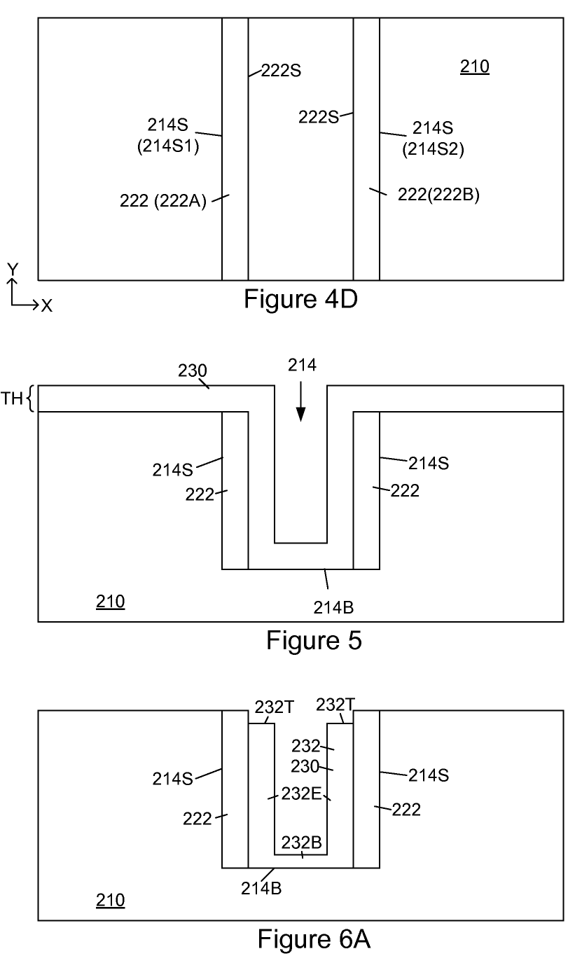

Referring to FIG. 4A, in one or more embodiments, the layer 220 may then be anisotropically etched to form sidewall spacer(s) 222 from the layer 220. The anisotropic etch may also be referred to as a spacer etch. The anisotropic etch may be a dry etch. The dry etch may, for example, comprise a dry plasma etch. The dry etch may, for example, comprise a reactive ion etch (RIE). The sidewall spacer(s) 222 may be formed over sidewall surface(s) 214S of the opening 214. In one or more embodiments, the sidewall spacer(s) 222 may be formed on (and in direct contact with) sidewall surface(s) 214S of the opening 214. The spacer 222 reduces the width of the opening 214. The sidewall spacer(s) 222 includes sidewall surface(s) 222S.

In one or more embodiments, the opening 214 may be a hole. Referring to FIG. 4B, if the opening 214 is a substantially cylindrical hole, then the spacer 222 may be substantially cylindrical in shape. Referring to FIG. 4C, if the opening is substantially square or rectangular, then the spacer 222 may have a substantially square or rectangular cross-section.

More generally, when the opening 214 is a hole, a sidewall spacer 222 may be formed which has a lateral cross-sectional shape that corresponds to the lateral cross-sectional shape of the opening 214. The spacer 222 may be tubular in shape. In one or more embodiments, the lateral cross-section of the spacer 222 may form a closed loop.

As noted, in one or more embodiments, the opening 214 may be a trench. In this case, the anisotropic etch of the layer 220 shown in FIG. 4D leads to the formation of two spacedly disposed sidewall spacers 222 depicted in FIG. 4D as sidewall spacer 222A and sidewall spacer 222B. Sidewall spacer 222A is formed over the sidewall surface 214S1 and the sidewall spacer 222B is formed over the sidewall surface 214S2. In the embodiment shown in FIG. 4D, the first and second sidewall spacers 222A and 222B may be substantially planar.

In one or more embodiments, the sidewall spacer(s) 222 may be dry removable. In one or more embodiments, the sidewall spacer(s) be removable without using a liquid. In one or more embodiments, the sidewall spacers 222 may be dry etchable. In one or more embodiments, the sidewall spacer(s) 222 may be etchable without using a liquid.

In one or more embodiments, the sidewall spacer(s) 222 may be stable at a temperature of about 200° C. In one or more embodiments, the sidewall spacer(s) 222 may be stable at a temperature of about 300° C. In one or more embodiments, the sidewall spacer(s) 222 may be stable at a temperature of about 400° C. In one or more embodiments, the sidewall spacer(s) 222 may be stable at a temperature of about 500° C. In one or more embodiments, the sidewall spacer(s) 222 may be stable at a temperature of about 600° C. In one or more embodiments, the sidewall spacer(s) 222 may be stable at a temperature of about 650° C. In one or more embodiments, the sidewall spacer(s) 222 may be stable at a temperature of about 700° C.

In one or more embodiments, the sidewall spacer may also be stable at temperatures below those indicated.

In one or more embodiments, the sidewall spacer(s) 222 may be dry removable and stable at a temperature of about 200° C. In one or more embodiments, the sidewall spacer(s) 222 may be dry removable and stable at a temperature of about 300° C. In one or more embodiments, the sidewall spacer(s) 222 may be dry removable and stable at a temperature of about 400° C. In one or more embodiments, the sidewall spacer(s) 222 may be dry removable and stable at a temperature of about 500° C. In one or more embodiments, the sidewall spacer(s) 222 may be dry removable and stable at a temperature of about 600° C. In one or more embodiments, the sidewall spacer(s) 222 may be dry removable and stable at a temperature of about 650° C. In one or more embodiments, the sidewall spacer(s) 222 may be dry removable and stable at a temperature of about 700° C.

In one or more embodiments, the sidewall spacer(s) may also be stable at temperatures below that indicated.

In one or more embodiments, the stability of the sidewall spacer(s) 222 may be a thermal stability. In one or more embodiments, the sidewall spacer(s) 222 should be able to withstand the temperatures of the deposition or growth process of the first conductive layer 230. In one or more embodiments, the sidewall spacer(s) 222 may be thermally stable during the deposition or growth of the first conductive layer 230 (described below).

Referring to FIG. 5, a layer 230 may then be formed over the top surface of the substrate 210 as well as over the sidewall surface(s) 222S of the sidewall spacer(s) 222 within the opening 214 as well as over the exposed portion of the bottom surface 214B of the opening 214. In one or more embodiments, the layer 230 may be a first conductive layer 230.

The first conductive layer 230 may be formed by a deposition process or by a growth process. In one or more embodiments, the first conductive layer 230 may be formed by a substantially conformal deposition process. Hence, the first conductive layer 230 may be substantially conformally deposited over the sidewall spacer(s) 222 within the opening 214. For example, the first conductive layer 230 may be substantially conformally deposited over the sidewall surface(s) 222S of the sidewall spacer(s) 222 as well as over the portion of the bottom surface 214B of opening 214 not covered by the sidewall spacer(s) 222. In one or more embodiments, the first conductive layer may be formed by a chemical vapor deposition process.

Referring to FIG. 5, the first conductive layer 230 may have a thickness TH. In one or more embodiments, the first conductive layer 230 may have a thickness of less than about 500 Angstroms. In one or more embodiments, the first conductive layer 230 may have a thickness of less than about 400 Angstroms. In one or more embodiments, the first conductive layer 230 may have a thickness of less than about 300 Angstroms. In one or more embodiments, the first conductive layer 230 may have a thickness of less than about 250 Angstroms. In one or more embodiments, the first conductive layer 230 may have a thickness of less than about 200 Angstroms. In one or more embodiments, the first conductive layer 230 may have a thickness of less than about 150 Angstroms. In one or more embodiments, the first conductive layer 230 may have a thickness of less than about 100 Angstroms.

In another embodiment, the deposition of first conductive layer 230 into the opening 214 need not be conformal and may at least partially fill the portion of the opening 214 interior to the sidewall spacer(s) 222.

In one or more embodiments, the first conductive layer 230 may be electrically coupled to at least a portion of the bottom surface of the opening 214.

In one or more embodiments, the first conductive layer 230 may comprise any conductive material. In one or more embodiments, the first conductive layer 230 may comprise a doped polysilicon. The doped polysilicon may be p-doped and/or n-doped. The doping may be performed in-situ or it may be performed, for example, by some type of ion implantation process or some other type of suitable process.

In one or more embodiments, the first conductive layer 230 may comprise a metallic material such as a pure metal or a metal alloy. The first conductive layer 230 may also be a composite or heterogeneous mixture of two or more conductive materials. The first conductive layer 230 may be formed as a layered stack of two or more layers (e.g. sub-layers of the first conductive layer 230). Each layer (e.g. sub-layer of the first conductive layer 230) of the stack may comprise a different conductive material.

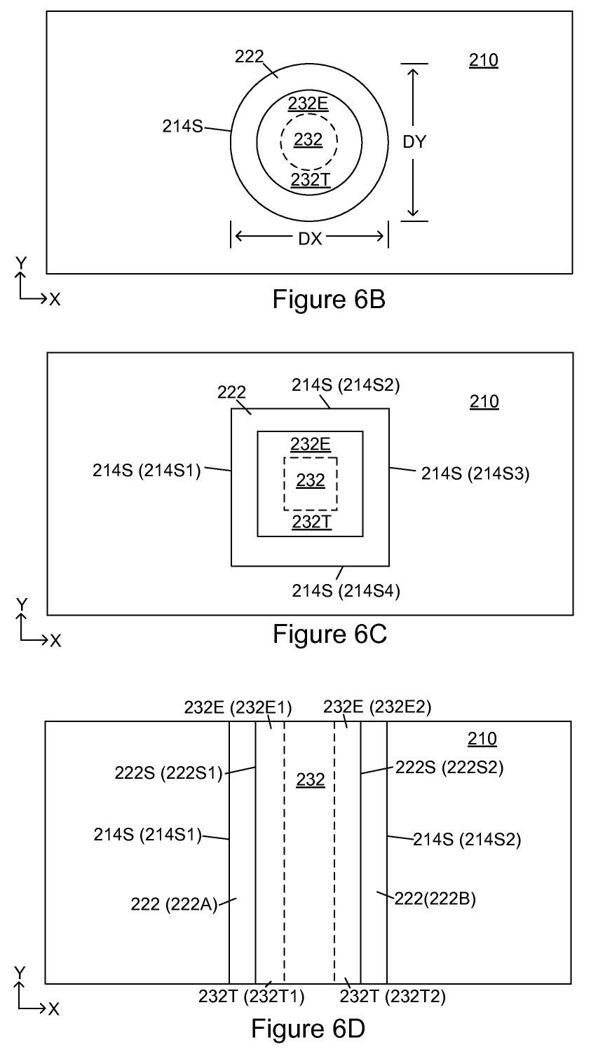

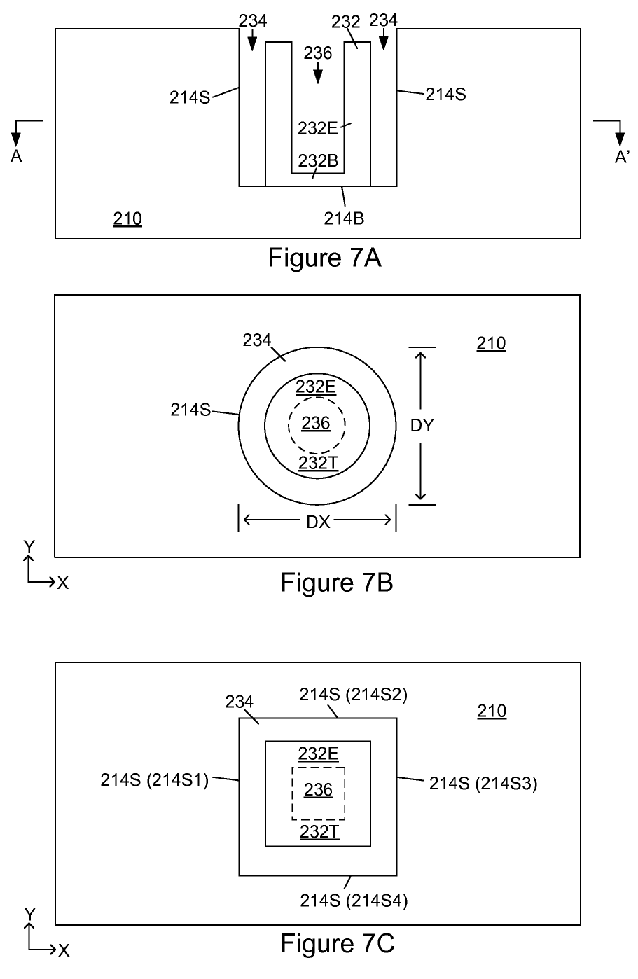

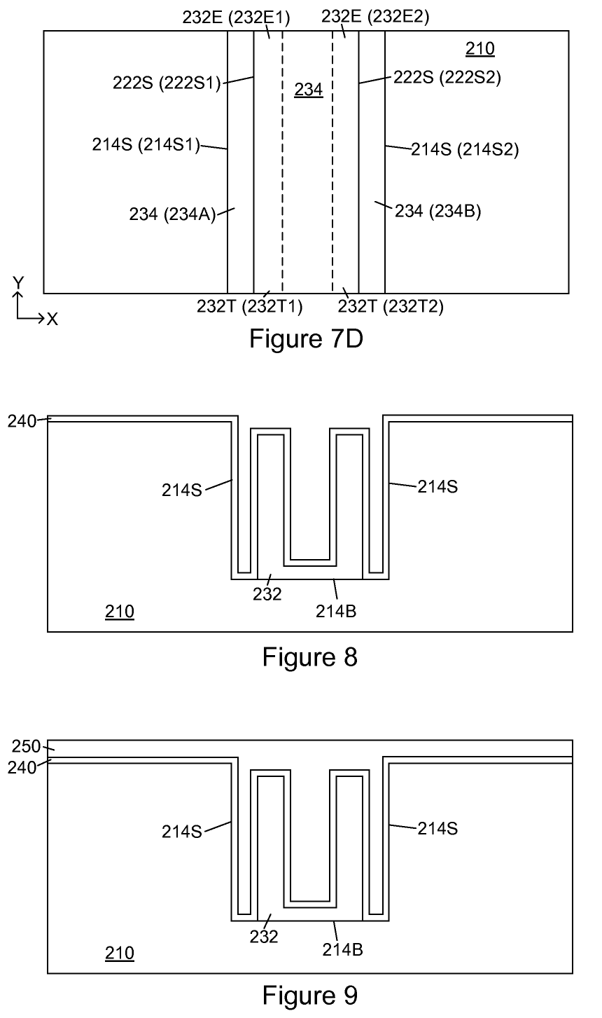

In one or more embodiments, the first conductive layer 230 may be deposited or grown in a conductive state. In one or more embodiments, the first conductive layer 230 may not be deposited or grown in a conductive state. Instead, in one or more embodiments, the first conductive layer 230 may be made conductive (for example, by a doping process) after it is deposited or grown. For example, an undoped polysilicon material (e.g. undoped polysilicon) may first be deposited and then this polysilicon material may be doped after deposition by, for example, an implantation process or any other type of suitable process (such as a diffusion process). In one or more embodiments, the first conductive layer 230 may be made conductive, for example, after it is etched to form the first conductive structure 232 as shown in FIG. 6A. In one or more embodiments, the first conductive layer 230 may be made conductive after it is etched but before the removal of the sidewall spacer(s) 222 (as shown in FIG. 7A). In one or more embodiments, the first conductive layer 230 may be made conductive after the removal of the sidewall spacer(s) 222 but before the formation of the dielectric layer 240 (as shown in FIG. 8). In one or more embodiments, it may be possible that the first conductive layer 230 may be made conductive after the formation of the dielectric layer 240 (as shown in FIG. 8).

Referring to FIG. 6A, the first conductive layer 230 shown in FIG. 5 may be etched so as to remove a portion of the first conductive layer 230 and leave a remaining portion of first conductive layer 230. In one or more embodiments, the etch may be a dry etch. The dry etch may be a plasma etch. The dry etch may be a reactive ion etch (RIE). In one or more embodiments, the etch process may be an anisotropic etch. The anisotropic etch may be a dry etch (for example, a dry plasma etch or a reactive ion etch).

The etching of the first conductive layer 230 forms a remaining portion of first conductive layer 230 which may also be referred to as first conductive structure 232. When the opening 214 is a hole, the first conductive structure 232 shown in FIG. 6A may be a cup-shaped structure. The cup-shaped structure includes an extension 232E that extends upward along the sidewall surface 222S of the sidewall spacer 222. The extension 232E may be substantially vertically disposed or oriented. When the opening 214 is a hole, the extension 232E may be tubular and have a lateral cross-section that corresponds to the lateral cross-section of the opening 214. Referring to FIG. 6B, when the opening 214 has a substantially circular cross-section, the extension 232E may have a substantially cylindrical shape. The extension 232E includes a top surface 232T which may be at substantially the same level as or below the top surface of the opening 214. Referring to FIG. 6C, when the opening 214 is substantially square, the extension 232E may have a substantially square cross-sectional shape. The extension 232E includes a top surface 232T which may be at substantially the same level as or below the top surface of the opening 214.

Referring to FIG. 6D, when the opening 214 is a trench, then the first conductive structure 232 may be u-shaped having two spacedly disposed extensions 232E depicted as extension 232E1 and 232E2. In this case, each extension 232E may be substantially planar. Also, in this case, each extension includes a top surface 232T, depicted as top surface 232T1 and top surface 232T2 which may be at substantially the same level as or below the top surface of the opening 214.

The sidewall spacer(s) 222 may then be removed from the structure shown in FIG. 6A so as to form the semiconductor structure shown in FIG. 7A. Generally, any method of removal may be used. As noted above, the sidewall spacer(s) 222 may comprise a carbon material. For example, the sidewall spacer(s) 222 may comprise a carbon allotrope. In one or more embodiments, the sidewall spacer(s) 222 may comprise graphite. In one or more embodiments, the sidewall spacer(s) 222 may comprise amorphous carbon. In one or more embodiments, the sidewall spacer(s) 222 may be removed using an etch process. In some embodiments, the etch process may be a dry etch process. In some embodiments, the dry etch process may be an ashing process such as a carbon ashing process.

In one or more embodiments, the dry etch process (for example, an ashing process such as a carbon ashing process) may be performed without a plasma. The semiconductor structure may be heated (for example, in a furnace such as an ashing furnace) to a temperature at or above about 600° C. In one or more embodiments, the temperature may be at or above about 700° C. The pressure within the furnace may be kept at about atmospheric pressure or even below atmospheric pressure. In some embodiments, the pressure may be about 10 mbar or greater. In some embodiments, the pressure may be about 25 mbar or greater. In some embodiments, the pressure may be about 100 mbar or less. In some embodiments, the etching may be performed in a batch furnace. In some embodiments, the etching may be performed in a batch furnace. In some embodiments, the etching may be performed as a rapid thermal process.

The semiconductor structure shown in FIG. 6A may be heated in the presence of a gas such as oxygen (O₂) or hydrogen (H₂). As noted above, the spacer(s) 222 may comprise a carbon material such as graphite. As a result of heating in the presence of oxygen, the graphite spacer 222 may be converted to carbon dioxide (CO₂) gas and/or carbon monoxide (CO) gas. As a result of heating the graphite in the presence of hydrogen, the graphite spacer 222 may be converted to methane (CH₄) gas. Hence, there may be no solid residue to deal with.

In one or more embodiments, the dry etch process (e.g. the carbon ashing process) may use a plasma. The plasma may, for example, be an oxygen plasma and/or a hydrogen plasma. In addition to the use of the plasma, fluorine may be introduced to enhance the etching of the plasma. In one or more embodiments, the plasma etching process may be performed at temperatures of about 300° C. or greater. In one or more embodiments, the plasma etching process may be performed at temperatures of about 400° C. or greater. In one or more embodiments, the plasma etching process may be performed at temperatures of about 500° C. or greater.

Hence, the oxygen or hydrogen plasma may serve as a reactive ion species. The reactive ion species may combine with the sidewall spacer material (e.g. a carbon material such as graphite) to form an ash which may be removed with the use of a vacuum pump. Typically, a monotomic (single atom) oxygen plasma may be created by exposing oxygen gas (O₂) or the hydrogen gas (H₂) to non-ionizing radiation. This process may be done under a vacuum in order to create a plasma.

In some embodiments, the plasma ashing process may be performed at low pressure. In some embodiments, the pressure may be sub-atmospheric. In some embodiments, the pressure may be about 100 mbar or less. In some embodiments, the pressure may be about 10E−3 mbar or greater. In some embodiments, the plasma power may about 500 Watts or greater. In some embodiments, the plasma power may be about 600 Watts or greater. In some embodiments, the plasma power may be about 700 Watts or greater. In some embodiments, the plasma power may be about 1500 Watts or less. In some embodiments, a rapid thermal process may be used.

Referring to FIG. 7A, after the sidewall spacer(s) 222 have been removed, the first conductive structure 232 remains in the opening 214.

Referring to FIG. 7A, it is seen that one or more gaps or spaces 234 may exist between the first conductive structure 232 and the sidewall surface(s) 214S.

Referring to FIGS. 7B and 7C, in the case in which the opening 214 is a hole, there may be a single gap or space 234 between the first conductive structure 232 and the sidewall surface 214S. Likewise, a gap or space 236 may exist interior to the extension 232E. FIG. 7B shows the embodiment in which the opening 214 is a substantially round hole while FIG. 7C shows the embodiment in which the opening 214 is a substantially square hole.

Referring to FIG. 7D, when the opening 214 is a trench, a first gap or space 234A may exist between the extension 232E1 and the sidewall surface 214S1. Likewise, a second gap or space 234B may exist between the extension 232E2 and the sidewall surface 214S2.

Referring to FIG. 8, a dielectric layer 240 may then be formed over the top surface of the substrate 210 as well as within the opening 214. The dielectric layer 240 may be formed over the sidewall surface(s) 214S and the exposed portion of bottom surface 214B of the opening 214. The dielectric layer 240 may also be formed over the surfaces of the first conductive structure 232 within the opening 214.

The dielectric layer 240 may be formed by a deposition process or by a growth process. The deposition process may be a substantially conformal deposition process. The dielectric layer 240 may thus be substantially conformally deposited over the exposed sidewall and bottom surfaces of the opening 214 as well as over the surfaces of the first conductive structure 232. The dielectric layer 240 may line the exposed surfaces of the opening 214 as well as the exposed surfaces of the first conductive structure 232.

The dielectric layer 240 may comprise any dielectric material. Examples include oxides (such as silicon oxide), nitrides (such as silicon nitride), oxynitrides (such as silicon oxynitride), or mixtures thereof. The dielectric layer 240 may also comprise a high-k material.

Referring to FIG. 9, a layer 250 may then be formed over the structure shown in FIG. 8 to form the semiconductor structure shown in FIG. 9. In one or more embodiments, the layer 250 may be a second conductive layer 250. The second conductive layer 250 may be formed over the dielectric layer 240 within the opening 214. A portion of the second conductive layer 250 may also be formed over that portion of the dielectric layer 240 which is over the top surface of the substrate 210.

The second conductive layer 250 may be formed by any type of deposition or growth process. In one or more embodiments, the deposition process may be a substantially conformal deposition process.

The second conductive layer 250 may comprise any conductive material. In one or more embodiments, the second conductive layer 250 may comprise a doped polysilicon. The doped polysilicon may be p-doped and/or n-doped. The doping may be performed in-situ or it may be performed, for example, by some type of implantation process.

In one or more embodiments, the second conductive layer 250 may comprise a metallic material such as a pure metal or a metal alloy. The second conductive layer 250 may also be a composite or heterogeneous mixture of two or more conductive materials. The second conductive layer 250 may be formed as a layered stack of two or more layers (e.g. sub-layers of the second conductive layer 250). Each layer (e.g. sub-layer of the second conductive layer) of the stack may comprise a different conductive material.

In one or more embodiments, the second conductive layer 250 may be deposited or grown in a conductive state. In one or more embodiments, the second conductive layer 250 may not be deposited or grown in a conductive state. Instead, the second conductive layer 250 may be made conductive (for example, by a doping process) after it is deposited or grown. For example, an undoped polysilicon material (e.g. undoped polysilicon) may be deposited and then this polysilicon material may be doped after deposition by an implantation process. The second conductive layer 250 may be made conductive any time after it is formed. For example, in one or more embodiments, it may be made conductive after it is deposited or grown but before the structure 252 shown in FIG. 10A is formed. In one or more embodiments, the second conductive layer 250 may be made conductive after the formation of structure 252.

Referring to FIG. 10A, a portion of the second conductive layer 250 may be removed by, for example, an etch process and/or a chemical mechanical polishing process. The etch process may, for example, be a recess etch or a plasma etchback process.

The etching and/or chemical mechanical polishing process of the second conductive layer 250 removed a portion of second conductive layer 250 and leaves a remaining portion of second conductive layer 250 shown in FIG. 10A. The remaining portion of second conductive layer 250 may be referred to as a second conductive structure 252. The second conductive structure 252 includes a base portion 252B as well as a one or more (and possible two or more) extensions 252E. Each extension 252E may be substantially vertically disposed and may extend downward.

In one or more embodiment, substantially all of the second conductive structure 252 may be formed within the opening 214. In one or more embodiments, at least a portion of the second conductive structure 214 may be formed above the top surface of the substrate 210.

In one or more embodiments, the opening 214 may be a hole. Referring to FIG. 10B, where the opening 214 is a hole having a lateral cross-section which is substantially circular, a first extension 252E1 (formed within the gap 234) may have a lateral cross-section which is also substantially circular so that the extension 252E1 is substantially cylindrical. The first extension 252E1 may be substantially vertically disposed and oriented downward. Also, a second extension 252E2 of the second conductive structure 252 is disposed within the interior space 236 defined by first conductive structure 232. The second extension 252E2 may be in the form of a conductive post or block. The second extension 252E2 may be substantially vertically disposed and oriented in a downward direction.

Referring to FIG. 10C, where the opening 214 is a hole having a lateral cross-section which is substantially square, an extension 252E1 (formed within the gap 234) may have a lateral cross-section which is also substantially square. Also, a second extension 252E2 of the second conductive structure 252 is disposed within the interior space 236 defined by first conductive structure 232. The second extension 252E2 may be in the form of a conductive post or block. The conductive post or block may have a lateral cross section which is substantially square. The second extension 252E2 may be substantially vertically disposed and oriented in a downward direction.

More generally, when the opening 214 is a hole, the first extension 252E1 may be tubular in shape where the cross-section of the extension 252E1 may correspond to the cross-section of the opening 214. In one or more embodiments, a tubular extension may have a lateral cross-section in the form of a closed loop.

FIG. 10D shows the embodiment where the opening 214 is a trench. In this embodiment, there are three spacedly disposed extensions E1, E2 and E3. Each of the extensions E1, E2, and E3 may be substantially vertically disposed and oriented downward. Likewise, each of the extensions may be substantially planar.

In one or more embodiments, the first conductive structure 232 may have one or more extensions 232E (and possibly two or more extensions 232E). Each of the extensions may be substantially vertically disposed. Each may be oriented upward. Each may be spacedly disposed from the other. The extensions 232E may each be electrically coupled to a base region 232B. The base regions 232B may be electrically coupled to the substrate 210 (e.g. a conductive portion of the substrate 210). In another embodiment, the extensions 232E may each be electrically coupled to the substrate (e.g. a conductive portion of the substrate 210) without the base region 232B.

In one or more embodiments, the second conductive structure 252 may have one or more extensions 252E (and possibly two or more extensions 252E). Each of the extensions 252E may be substantially vertically disposed. Each may be oriented downward. Each may be spacedly disposed from the other. Each of the extensions 252E may be electrically coupled to a base region 252B.

The extensions 232E and the extensions 252E may be arranged so that they are alternatingly disposed.

In one or more embodiments, at least one of the extensions 232E may have a lateral thickness which is less than that which can be achieved using photolithography. In one or more embodiments, the lateral thickness may be less than about 500 Angstroms. In one or more embodiments, the lateral thickness may be less than about 400 Angstroms. In one or more embodiments, the lateral thickness may be less than about 300 Angstroms. In one or more embodiments, the lateral thickness may be less than about 200 Angstroms. In one or more embodiments, the lateral thickness may be less than about 150 Angstroms. In one or more embodiments, the lateral thickness may be less than about 100 Angstroms. An example of a lateral thickness of an extension 232E is shown as lateral thickness TH1 of extension 232E in FIG. 10B.

In one or more embodiments, at least one of the extensions 252E may have a lateral thickness which is less than that which can be achieved using photolithography. In one or more embodiments, the lateral thickness may be less than about 500 Angstroms. In one or more embodiments, the lateral thickness may be less than about 400 Angstroms. In one or more embodiments, the lateral thickness may be less than about 300 Angstroms. In one or more embodiments, the lateral thickness may be less than about 200 Angstroms. In one or more embodiments, the lateral thickness may be less than about 150 Angstroms. In one or more embodiments, the lateral thickness may be less than about 100 Angstroms. An example of a lateral thickness of an extension 252E is shown as lateral thickness TH2 of extension 252E1 in FIG. 10B.

The semiconductor structures 310 shown in FIGS. 10A-D comprise a capacitor 320. The capacitor 320 may be at least partially formed within the opening 214. The capacitor 320 may be referred to as a trench capacitor even through the opening 214 may be a hole or a trench. The semiconductor structures 310 may represent a semiconductor chip or semiconductor device. The semiconductor structures 310 may be part of a semiconductor chip or a semiconductor device. The semiconductor chip may include an integrated circuit. The capacitor 320 may be part of the integrated circuit. In one or more embodiments, the capacitor 320 may be referred to as an integrated capacitor.

The capacitor 320 comprises a first capacitor electrode, a second capacitor electrode and a capacitor dielectric between the first and second capacitor electrodes. The first capacitor electrode of capacitor 320 comprises at least the first conductive structure 232. In one or more embodiments, the first capacitor electrode may further comprise at least a portion (such as a conductive portion) of the substrate 210. This portion of the substrate may be a portion which is adjacent or proximate to the opening 214. This adjacent or proximate portion of the substrate 210 may be a conductive portion of the substrate. It may be an n and/or p doped monocrystalline silicon material. The first conductive structure 232 may be electrically coupled to the bottom surface of the opening 214. The first conductive structure 232 may be electrically coupled to the conductive portion of the substrate.

The capacitor 310 may further comprise a capacitor dielectric. The capacitor dielectric comprises the dielectric layer 240.

The second capacitor electrode may comprise at least the second conductive structure 252.

Another embodiment of the invention is shown in FIG. 11. FIG. 11 shows a capacitor structure 320. The embodiment shown in FIG. 11 shows that the embodiment shown in FIGS. 10A-D may be extended to increase the number of extensions 232E and the number of extensions 252E. In the case in which the opening 214 is a hole, the extensions 232E may comprise a plurality of concentric extensions.

In one or more embodiments, the first conductive structure 232 (as hence the first electrode) may include at least one upwardly extending vertical extension (for example, N where N≧1) while the second conductive structure 252 may include a plurality of downwardly extending vertical extensions (for example, N+1 where N≧1).

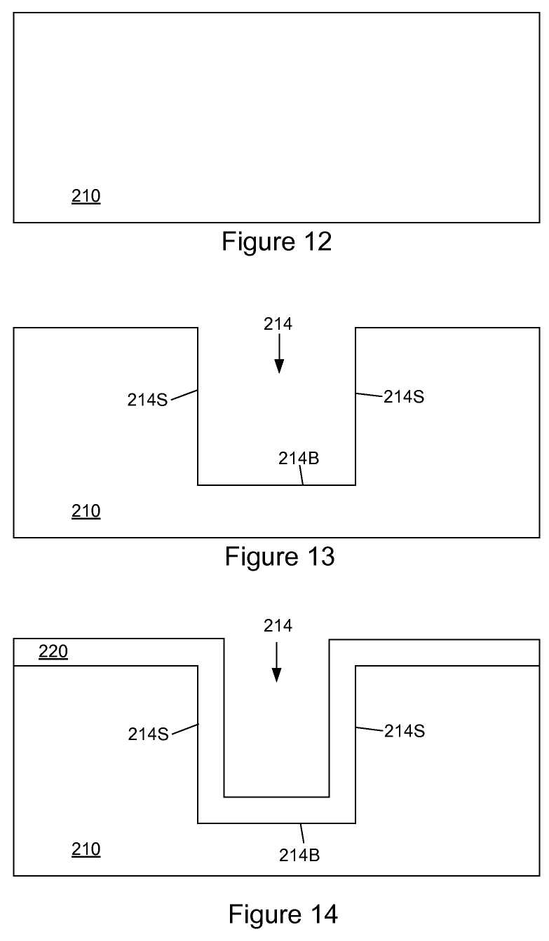

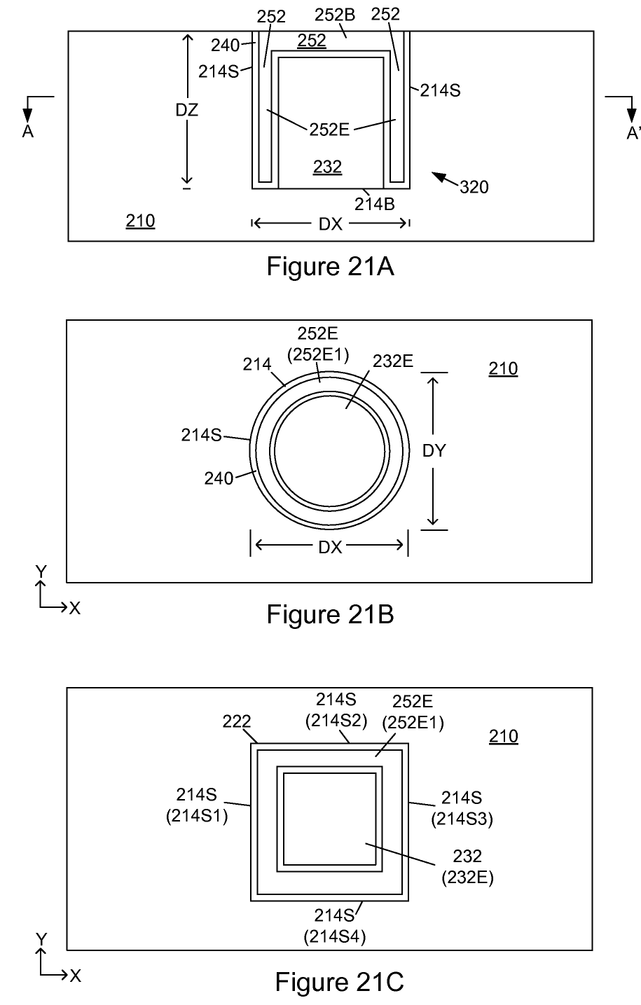

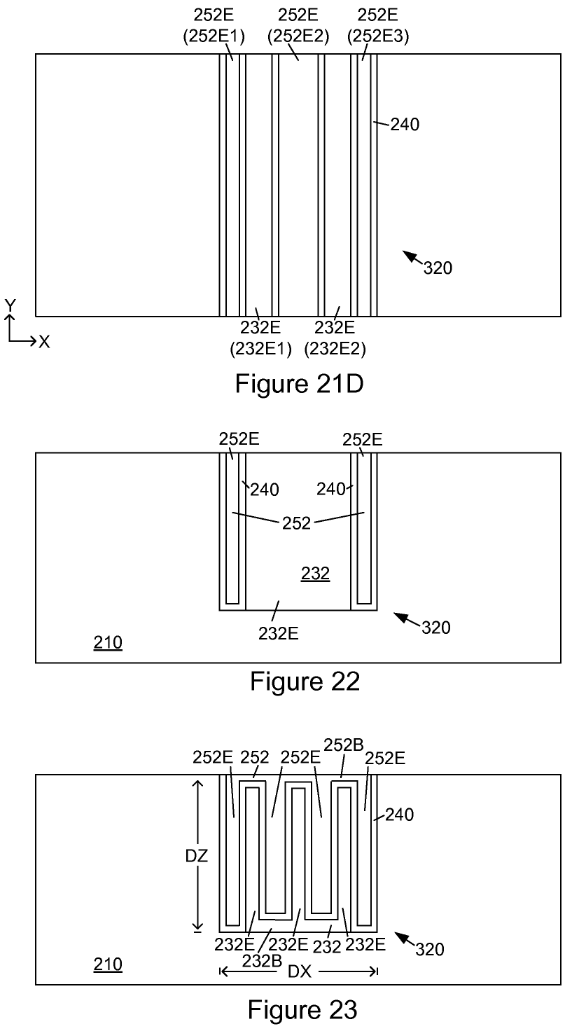

Another embodiment of a capacitor of the present invention is the capacitor 320 shown in FIGS. 21A-D. The process for forming the capacitor 320 is shown in FIG. 12 through 21A-D. This process is also an embodiment of the present invention.

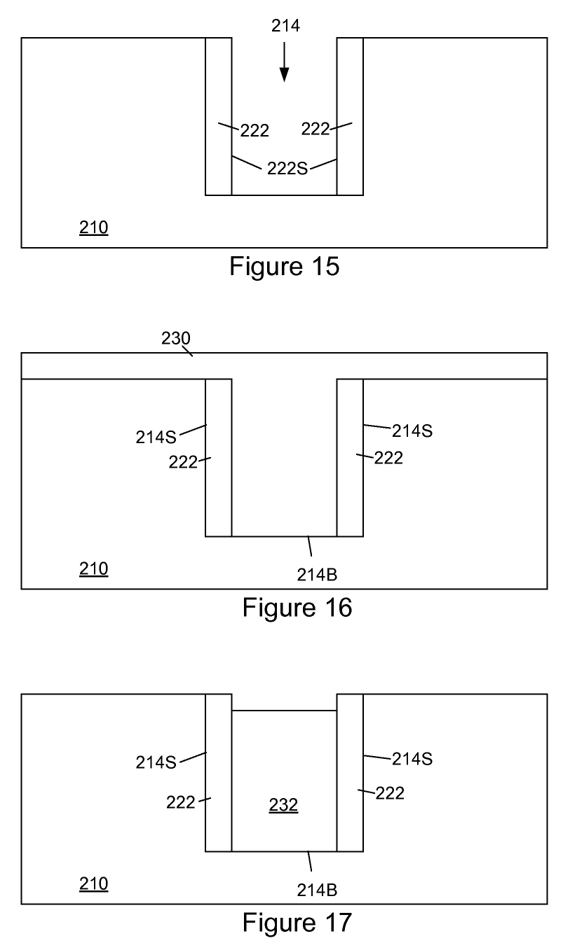

The processing steps shown in FIG. 12 through 15 are the same as the processing steps shown in FIGS. 1 through 4A-D and the explanation has already been provided above. FIG. 15 shows one or more sidewall spacers 222 formed over the one or more sidewall surfaces of opening 214. As noted above, the opening 214 may be a hole or a trench.

Referring to FIG. 16, a layer 230 is formed over the top surface of the substrate 210 and also within the opening 214. In one or more embodiments, the layer 230 is a first conductive layer 230. The first conductive layer 230 may be formed by a deposition process or growth process. In the embodiment shown in FIG. 16, the first conductive layer 230 fills the opening 214. However, in another embodiment, the first conductive layer 230 may be formed so as to only partially fill the opening 214.

In one or more embodiments, the first conductive layer 230 may be deposited or grown in a conductive state. In one or more embodiments, the first conductive layer 230 may not be deposited or grown in a conductive state and it may be made conductive in a later processing step. As an example, the first conductive layer 230 may be deposited as undoped polysilicon and then doped in a later processing step.

Referring to FIG. 17, a portion of the first conductive layer 230 may be removed to leave a remaining portion of first conductive layer 230 which may also be referred to as a first conductive structure 232. In one or more embodiments, the first conductive structure 232 may be formed as a post or block. The partial removal of the first conductive layer 230 may be performed by an etch process, such as a dry etch process. The dry etch process may be a dry plasma etch process. The dry etch process may be a reactive ion etch (RIE). The top of the first conductive structure 232 may be at or below the top of the opening 214.

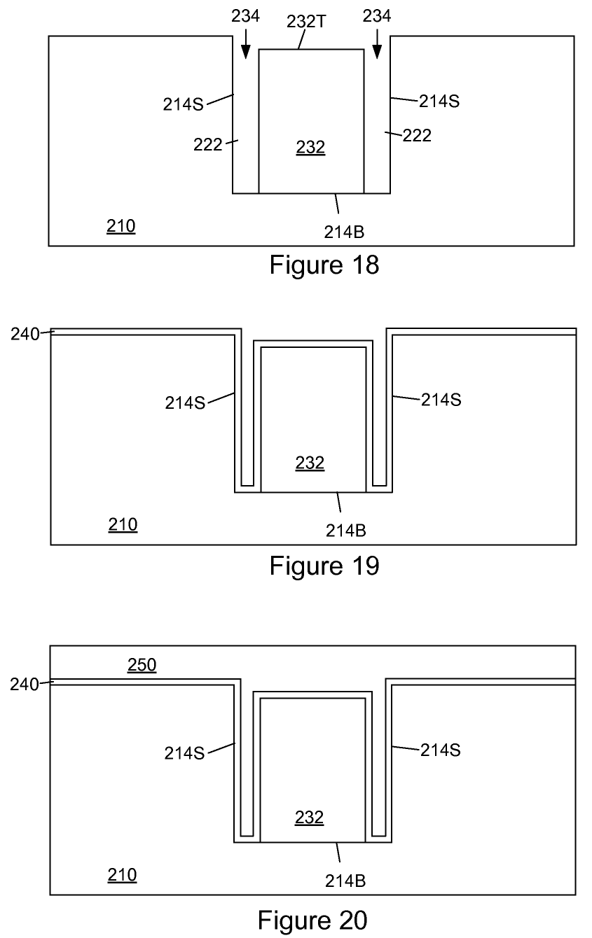

Referring to FIG. 18, the sidewall spacer(s) 222 shown in FIG. 17 may be removed to form the structure shown in FIG. 18. The removal process may be the same as that described above with regards, for example, the sidewall spacer(s) 222 shown in FIG. 6A-D (removed to form the structures shown in FIGS. 7A-D). For example, the sidewall spacer(s) 222 may be removed by an etch process such as by an ashing process. The sidewall spacer(s) 222 may comprise a carbon material. Examples of the carbon material have been provided above. For example, the carbon material may be a carbon allotrope. The carbon material may, for example, be graphite, graphene or amorphous carbon. In this case, the ashing process may be a carbon ashing process.

After the removal of the sidewall spacer(s) 222, one or more gaps 234 remains between the first conductive structure 232 and the sidewall surface(s) 214S of the opening 214. The first conductive structure 232 may have a top surface 232T. The top surface 232T may be at or below the top surface of the substrate 210.

Referring to FIG. 19, a dielectric layer 240 may be formed within the opening 214. The dielectric layer 240 may be formed within the one or more gap(s) 234. The dielectric layer 240 may be formed by a substantially conformal deposition process so as to line the sidewall surface(s) 214S as well as the exposed portions of the bottom surface of the opening 214. The dielectric layer 240 may also line the sidewall and top surfaces of the first conductive structure 232.

Referring to FIG. 20, a layer 250 may be formed over the dielectric layer 240 and within the opening 214. In one or more embodiments, the layer 250 may be a second conductive layer 250. The dielectric layer 240 may be disposed within the gap(s) 234.

In one or more embodiments, the second conductive layer 250 may be deposited or grown in a conductive state. In one or more embodiments, the second conductive layer 250 may not be deposited or grown in a conductive state but may be made conductive in a later processing step. For example, the second conductive layer may be deposited as undoped polysilicon and then doped at a later processing step.

Referring to FIG. 21, the second conductive layer 250 may then be etched or subjected to a chemical mechanical polishing process to form a remaining portion of the second conductive layer 250 which may also be referred to as a second conductive structure 252. The etching may comprise a dry etch such as a plasma etch. The etching may comprise a reactive ion etch (RIE).

FIG. 21A shows a capacitor 320. The capacitor 320 includes a first capacitor electrode, a second capacitor electrode and a capacitor dielectric disposed between the first and second capacitor electrodes. The first capacitor electrode comprises at least the first conductive structure 232. The first capacitor electrode may further include at least a portion of the substrate 210. This may be a conductive portion. This may be a portion of the substrate which is proximate or adjacent to the opening 214. This proximate or adjacent portion of the substrate 210 may be a conductive portion which may, for example, comprise a doped monocrystalline silicon. The doping may be n and/or p type doping.

The second capacitor electrode comprises at least the second conductive structure 252. The second conductive structure 252 may include a base portion 252B. The second conductive structure 252 may further include one or more extensions 252E (and possibly two or more extensions 252E). The extension(s) 252E may be substantially vertically disposed.

The capacitor dielectric comprises at least the dielectric layer 240. The first conductive structure 232 shown in FIG. 21A may, for example, be in the form of a post or block. The shape of the first conductive structure 232 depends upon the shape of the opening 214. As noted the opening 214 may be a hole or a trench. The hole may have any shape. FIG. 21B shows the lateral cross-section through AA′ of FIG. 21A when the opening 214 is a circular hole. FIG. 21C shows the lateral cross-section through AA′ of FIG. 21A when the opening 214 is a square hole. FIG. 21D shows the lateral cross-section through AA′ of FIG. 21A when the opening 214 is a trench.

When the opening 214 is a hole, the second conductive structure 252 may be in the shape of an upside down cup-structure having a base portion 252B and a downward extending vertical extension 252E. Generally, when the opening 214 is a hole, the extension 252E may be tubular in shape and may have a cross-section taking the shape of the opening 214. Hence, in the case in which the lateral cross-section of the opening 214 is in the shape of a substantially circular hole, the extension 252E may be substantially cylindrically shaped. When the opening 214 is a trench, the conductive structure 252 may be an upside down U-shape structure having a base portion 252B and extensions 252E which may be in the form of two spacedly disposed extensions 252E1 and 252E2 which may each be substantially planar.

FIG. 22 shows a capacitor structure 320 which is another embodiment of the invention. The capacitor structure 320 shown in FIG. 22 is similar to that shown in FIGS. 21A-D except that there is no base portion 252B.

FIG. 23 shows a capacitor structure 320 which is another embodiment of the invention. The capacitor 320 shown in FIG. 23 includes a first conductive structure 232 and a second conductive structure 252. The first conductive structure 232 may include the base portion 232B. The first conductive structure 232 may include one or more extensions 232E. The extensions 232E may be substantially vertically disposed. The extensions 232E may be oriented upward and may be electrically coupled to the base portion 232B. The base portion 232B may be electrically coupled to a conductive portion of the substrate 210.

The second conductive structure 252 may include a base portion 252B. The second conductive structure 252 may include one or more extensions 252E. The extensions 252E may be substantially vertically disposed. The extensions 232E may be oriented downward and may be electrically coupled to the base portion 232B. The base portion 252B may be electrically coupled to another conductive element.

Referring to the embodiments of the capacitors 320 shown, for example, in FIGS. 10A-D, 21A-D, 22 and 23, it is seen that the opening 214 has a depth DZ and a width DX. In one or more embodiments, the depth DZ may be at least 10 times greater than the width DX. In one or more embodiments, the depth DZ may be at least 15 times greater than the width DX. In one or more embodiments, the depth DZ may be at least 20 times greater than the width DX. In one or more embodiments, the depth DZ may be at least 25 times greater than the width DX. In one or more embodiments, the depth DZ may be at least 30 times greater than the width DX. In one or more embodiments, the depth DZ may be at least 40 times greater than the width DX. In one or more embodiments, the depth DZ may be at least 50 times greater than the width DX. In one or more embodiments, the depth DZ may be at least 100 times greater than the width DX.

In one or more embodiments, the first and second conductive layers (for example, first conductive layer 230 and second conductive layer 250 described herein), the first and second conductive structures (for example, first conductive structure 232 and second conductive structure 252) as well as any other conductive layers, regions or structures described herein may comprise any conductive material. In one or more embodiments, the conductive material may comprise a doped polysilicon. The doped polysilicon may be p-doped and/or n-doped. The doping may be performed in-situ or it may be performed, for example, by some type of ion implantation process, diffusion process or any other type of suitable process. Generally, the doping may occur at any point in the manufacturing process.

In one or more embodiments, the conductive material may comprise a metallic material. The metallic material may comprise a pure metal. The metallic material may comprise a metal alloy. The metallic material may comprise, without limitation, one or more periodic table elements from the group consisting of Al (aluminum), Cu (copper), Au (gold), Ag (silver), W (tungsten), Ti (titanium), and Ta (tantalum).

As possible examples, the conductive material may comprise one or more materials selected from the group consisting of pure aluminum, aluminum alloy, pure copper, copper alloy, pure gold, gold alloy, pure silver, silver alloy, pure tungsten, tungsten alloy, pure titanium, titanium alloy, pure tantalum, and tantalum alloy. It is understood that the pure metals may include small amounts of trace impurities. As additional examples, the conductive material may comprise a nitride. The metal nitride may be a refractory metal nitride. Examples of conductive material which may be used include, but not limited to, TiN, TaN and WN.

The conductive material may also comprise a conductive polymer. The conductive material may comprise a non-metallic conductive material. In one or more embodiments, the material may be doped. The doping may, for example, be in-situ or it may be performed by an implantation process.

The conductive material may also be a composite or heterogeneous mixture of two or more conductive materials. In one or more embodiments, conductive layers and structures may be formed as a layered stack of two or more layers. Each layer may comprise a different conductive material.

As noted above, in one or more embodiments, one or more of the conductive layers or structures described herein may not be conductive when deposited or grown but may be made conductive after deposition or growth.

In one or more embodiments, the layers used to form the capacitor electrodes (for example, the layer 230 and the layer 250 described above) may comprise any suitable electrode material for a capacitor electrode.

The dielectric layers described herein may comprise any dielectric material. In one or more embodiments, the dielectric material may include an oxide, a nitride, an oxynitride and combinations thereof. Examples of possible oxides include, but not limited to silicon oxide, aluminum oxide, hafnium oxide, tantalum oxide, and combinations thereof. Examples of possible nitrides include, but not limited to, silicon nitride. Examples of possible oxynitrides include, but not limited to, silicon oxynitride.

The dielectric material may comprise a high-k material. The high-k material may have a dielectric constant greater than that of silicon dioxide. In one or more embodiments, the high-k material may have a dielectric constant greater that 3.9. In one or more embodiments, the dielectric may be a gas. In one or more embodiments, the dielectric may be air. In one or more embodiments, the dielectric may be a vacuum.

It is noted that in one or more embodiments, the techniques described herein may provide a capacitor with a higher specific capacitance. It is noted that in one or more embodiments, the techniques described herein may provide a capacitor with a higher surface area.

One or more embodiments may relate to a method of making a capacitor, comprising: providing a substrate; forming an opening within the substrate; forming a sidewall spacer over a sidewall surface of the opening; forming a first conductive layer within the opening after forming the sidewall spacer; removing the sidewall spacer; forming a dielectric layer over the first conductive layer within the opening; and forming a second conductive layer over the dielectric layer within the opening. In one or more embodiments, the substrate may be a semiconductor substrate. In one or more embodiments, the capacitor may be a trench capacitor. In one or more embodiments, the substrate may be semiconductor substrate.

One or more embodiments may relate to a method of making a trench capacitor, comprising: providing a substrate; forming an opening within the substrate; forming a sidewall spacer over a sidewall surface of the opening; forming a first conductive layer within the opening after forming the sidewall spacer; removing the sidewall spacer; forming a dielectric layer over the first conductive layer within the opening; and forming a second conductive layer over the dielectric layer within the opening. In one or more embodiments, the substrate may be a semiconductor substrate.

One or more embodiments may relate to a method of making a capacitor, comprising: forming an opening within a substrate; forming a first layer over a sidewall of the opening; forming a first electrode material within the opening after forming the layer; removing the first layer after forming the first electrode material; forming a dielectric material over the first electrode material within the opening; and forming a second electrode material over the dielectric material within the opening. In one or more embodiments, the capacitor may be a trench capacitor. In one or more embodiments, the substrate may be a semiconductor substrate. In one or more embodiments, the first layer may comprise a sidewall spacer. In one or more embodiments, the first layer may comprise at least one sidewall spacer. In one or more embodiments, the first layer may be a sidewall spacer.

One or more embodiments may relate to a semiconductor device, comprising: a substrate comprising an opening; a capacitor at least partially disposed within the opening, the capacitor including a first conductive structure disposed within the opening, a dielectric layer overlying the first conductive structure within the opening and a second conductive structure overlying the dielectric layer within the opening, the first conductive structure and/or the second conductive structure comprising at least one substantially vertical extension, the extension having a lateral thickness less than about 500 Angstroms.

The disclosure herein is presented in the form of detailed embodiments described for the purpose of making a full and complete disclosure of the present invention, and that such details are not to be interpreted as limiting the true scope of this invention as set forth and defined in the appended claims.

What is claimed is:

1. A method of making a trench capacitor, comprising:
providing a substrate;
forming an opening within said substrate;
forming a sidewall spacer over a sidewall surface of said opening;
forming a first conductive layer within said opening after forming said sidewall spacer;
removing said sidewall spacer;
forming a dielectric layer over said first conductive layer within said opening; and
forming a second conductive layer over said dielectric layer within said opening.

2. The method of claim 1, wherein said sidewall spacer comprises carbon.

3. The method of claim 1, wherein said sidewall spacer comprises graphite.

4. The method of claim 1, wherein said sidewall spacer comprises a material which is stable at least at a temperature of about 200° C.

5. The method of claim 1, wherein said sidewall spacer comprises a material which is stable at least at a temperature of about 300° C.

6. The method of claim 1, wherein said sidewall spacer comprises a material which is stable at least at a temperature of about 400° C.

7. The method of claim 1, wherein said forming said first conductive layer comprises depositing said first conductive layer, said sidewall spacer comprising a material which is thermally stable during said depositing said first conductive layer.

8. The method of claim 1, wherein said sidewall spacer comprises a material which is dry removable.

9. The method of claim 8, wherein said sidewall spacer comprises a material which is stable at a temperature of about 200° C.

10. The method of claim 8, wherein said sidewall spacer comprises a material which is stable at a temperature of about 300° C.

11. The method of claim 8, wherein said sidewall spacer comprises a material which is stable at a temperature of about 400° C.

12. The method of claim 8, wherein said forming said first conductive layer comprises depositing said first conductive layer, said sidewall spacer comprising a material which is thermally stable during said depositing said first conductive layer.

13. The method of claim 1, wherein said removing said sidewall spacer comprises a dry etching process.

14. The method of claim 1, wherein said removing said sidewall spacer comprises an ashing process.

15. The method of claim 1, wherein said forming said first conductive layer comprises a substantially conformal deposition process.

16. The method of claim 1, further comprising anisotropically etching said first conductive layer before removing said sidewall spacer and before forming said dielectric layer.

17. The method of claim 1, wherein said forming said dielectric layer comprises a substantially conformal deposition.

18. The method of claim 1, wherein said forming said dielectric layer occurs after said removing said sidewall spacer.

19. The method of claim 1, wherein said removing said sidewall spacer comprises a dry removal process.

20. The method of claim 1, wherein said removing said sidewall spacer comprises a dry etching process.

21. The method of claim 1, wherein said removing said sidewall spacer comprises an ashing process.

22. The method of claim 1, wherein said opening is a hole or a trench.

23. The method of claim 1, wherein said substrate is a semiconductor substrate.

24. A method of making a capacitor, comprising:
forming an opening within a substrate;
forming a first layer over a sidewall of said opening;
forming a first electrode material within said opening after forming said layer;
removing said first layer after forming said first electrode material;
forming a dielectric material over said first electrode material within said opening; and
forming a second electrode material over said dielectric material within said opening.

25. The method of claim 24, wherein said first electrode material and said second electrode material comprise one or more conductive materials.

26. The method of claim 24, wherein said first electrode material and/or said second electrode material comprises a polysilicon material.

27. The method of claim 24, wherein said opening is a hole or a trench.

28. The method of claim 24, wherein said first layer comprises a carbon material.

29. The method of claim 28, wherein said carbon material comprises graphite.

30. The method of claim 24, wherein said first layer is stable at a temperature of about 200° C.

31. The method of claim 24, wherein said first layer is stable at a temperature of about 300° C.

32. The method of claim 24, wherein said first layer is stable at least at a temperature of about 400° C.

33. The method of claim 24, wherein said forming said electrode material comprise depositing said electrode material, said first layer being thermally stable during said depositing said electrode material.

34. The method of claim 24, wherein said first layer is dry removable.

35. The method of claim 34, wherein said first layer is stable at a temperature of about 200° C.

36. The method of claim 34, wherein said first layer is stable at a temperature of about 300° C.

37. The method of claim 34, wherein said first layer is stable at a temperature of about 400° C.

38. The method of claim 34, wherein said forming said electrode material comprise depositing said electrode material, said first layer being thermally stable during said depositing said electrode material.

39. The method of claim 24, wherein said removing said first layer comprises a dry removal process.

40. The method of claim 24, wherein said removing said first layer comprises a dry etching process.

41. The method of claim 24, wherein said removing said first layer comprises an ashing process.

42. The method of claim 24, wherein said forming said first electrode material comprises a substantially conformal deposition.

43. The method of claim 24, wherein said forming said dielectric material comprises a substantially conformal deposition.

44. The method of claim 24, wherein said forming said layer comprises a substantially conformal deposition.

45. The method of claim 44, wherein said forming said first layer comprises an anisotropic etch after said substantially conformal deposition.

46. The method of claim 24, wherein said first layer comprises a sidewall spacer.

47. The method of claim 24, wherein said capacitor is a trench capacitor.

48. The method of claim 47, wherein said opening is a hole or a trench.

49. The method of claim 24, wherein said substrate is a semiconductor substrate.

50. The method of claim 24, wherein said first electrode material comprises a first conductive material and said second electrode material comprises a second conductive material.

51. The method of claim 50, wherein said first conductive material and said second conductive material are the same material.

52. The method of claim 24, wherein said first electrode material and said second electrode material are the same material.

53. A semiconductor device, comprising:
a substrate comprising an opening;
a trench capacitor at least partially disposed within said opening, said capacitor including a first conductive structure disposed within said opening, a dielectric layer overlying said first conductive structure within said opening and a second conductive structure overlying said dielectric layer within said opening, said first conductive structure and/or said second conductive structure comprising at least one substantially vertical extension, said extension having a lateral thickness less than about 500 Angstroms.

54. The device of claim 53, wherein said lateral thickness is less than about 300 Angstroms.

55. The device of claim 53, wherein said lateral thickness is less than about 100 Angstroms.

56. The device of claim 53, wherein said extension is tubular.

57. The device of claim 53, wherein said extension is substantially cylindrical.

58. The device of claim 53, wherein said opening has a vertical dimension to lateral dimension aspect ratio of at least 15 to 1.

59. The device of claim 53, wherein said opening has a vertical dimension to lateral dimension aspect ratio of at least 20 to 1.

60. The device of claim 53, wherein said substrate is a semiconductor substrate.

61. The device of claim 53, wherein said opening is a hole or a trench.
